(19) United States
(12) Patent Application Publication
(10) Pub. No.: US 2016/0264814 A1
(43) Pub. Date: Sep. 15, 2016

(54) MULTILAYER GRAPHENE STRUCTURE REINFORCED WITH POLYAROMATIC INTERSTITIAL LAYERS

(71) Applicant: International Business Machines Corporation, Armonk, NY (US)

(72) Inventors: JOSE MIGUEL LOBEZ COMERAS, New York, NY (US); Christos D. Dimitrakopoulos, Baldwin Place, NY (US); Aaron D. Franklin, Croton on Hudson, NY (US); Joshua T. Smith, Croton on Hudson, NY (US)

(21) Appl. No.: 14/747,346

(22) Filed: Jun. 23, 2015

Related U.S. Application Data
(63) Continuation of application No. 14/642,249, filed on Mar. 9, 2015.

(51) Int. Cl. C09D 165/00; C23C 16/02; C23C 16/26

(52) U.S. Cl. CPC C09D 165/00; C23C 16/26; C23C 16/0272

(57) ABSTRACT

In one embodiment, a multilayer graphene structure includes a first layer of graphene, a second layer of graphene; and an interstitial layer bonding the first layer of graphene to the second layer of graphene, wherein the interstitial layer comprises a polyaromatic compound. In another embodiment, a multilayer graphene structure is fabricated by providing a first layer of graphene, providing a second layer of graphene, and providing a first interstitial layer between the first layer of graphene and the second layer of graphene, wherein the first interstitial layer comprises a polyaromatic compound. In another embodiment, a multilayer graphene structure includes a plurality of layers of graphene and a plurality of interstitial layers formed of at least one polyaromatic compound, where each pair of the layers of graphene is bonded by one of the interstitial layers, such that a structure comprising alternating layers of graphene and interstitial layers is formed.

### REFERENCE TO GOVERNMENT FUNDING

This invention was made with Government support under Contract No. HR0011-12-C-0038, awarded by the Defense Advanced Research Projects Agency (DARPA). The Government has certain rights in this invention.

### FIELD OF THE DISCLOSURE

This disclosure relates generally to the field of materials science, and relates more specifically to the formation of multilayer graphene structures.

### BACKGROUND OF THE DISCLOSURE

Graphene is the strongest known material in the world. Additionally, it is lightweight, flexible, and conducts heat and electricity with great efficiency. Graphene's stability is due to its tightly packed carbon atoms and an sp² orbital hybridization, which is the result of pₓ and p_{y} orbitals that form a σ-bond. The final p_{z} electron makes up a π-bond. The π-bonds hybridize together to form the π- and π*-bands. Owing to its unique structure and resulting properties, graphene's use has been explored in semiconductor, electronic, mechanical, medical, military, and other applications.

### SUMMARY OF THE DISCLOSURE

In one embodiment, a multilayer graphene structure includes a first layer of graphene, a second layer of graphene; and an interstitial layer bonding the first layer of graphene to the second layer of graphene, wherein the interstitial layer comprises a polyaromatic compound.

In another embodiment, a multilayer graphene structure is fabricated by providing a first layer of graphene, providing a second layer of graphene, and providing a first interstitial layer between the first layer of graphene and the second layer of graphene, wherein the first interstitial layer comprises a polyaromatic compound.

In another embodiment, a multilayer graphene structure includes a plurality of layers of graphene and a plurality of interstitial layers formed of at least one polyaromatic compound, where each pair of the layers of graphene is bonded by one of the interstitial layers, such that a structure comprising alternating layers of graphene and interstitial layers is formed.

### BRIEF DESCRIPTION OF THE DRAWINGS

The teachings of the present disclosure can be readily understood by considering the following detailed description in conjunction with the accompanying drawings, in which:

FIG. 1 illustrates a cross sectional view of one embodiment of a multilayer graphene structure, according to the present disclosure; and

FIG. 2 is a flow diagram illustrating a high level method for fabricating a multilayer graphene structure, according to embodiments of the present disclosure.

### DETAILED DESCRIPTION

In one embodiment, the present disclosure is related to a multilayer graphene structure reinforced with polyaromatic interstitial layers. A multilayer graphene structure ideally would be able to capitalize on the combined strength of the individual graphene layers in a manner that would result in improved overall strength. However, graphene sheets manufactured according to conventional techniques tend to exhibit weak interlayer π-bond interactions and in-plane bonds can be weakened in the presence of domain boundaries in graphene grown by chemical vapor deposition (CVD). As a result of the weaker π-π interactions, if one were to attempt to stack a number of these graphene sheets to capitalize on their combined strength, the graphene sheets would be loaded one sheet at a time due to interlayer slip, rather than all graphene sheets cooperating to uniformly support a load. Thus, the stacked structure would fail to fully exploit the potential of the material stack.

One embodiment of the present disclosure coats a layer of graphene with a monolayer of polyaromatic compounds that self-assemble on graphitic materials (such as graphene). After coating the layer of graphene, another layer of graphene can be deposited on the monolayer of polyaromatic compounds, such that the monolayer essentially acts as a glue that bonds the layers of graphene to each other. This process can be repeated a number of times to produce a multilayer graphene structure with interstitial monolayers of polyaromatic compounds. The resultant multilayer structure, which is characterized by strengthened bonds between the graphene layers, allows the individual layers of graphene to uniformly share a load applied to the structure.

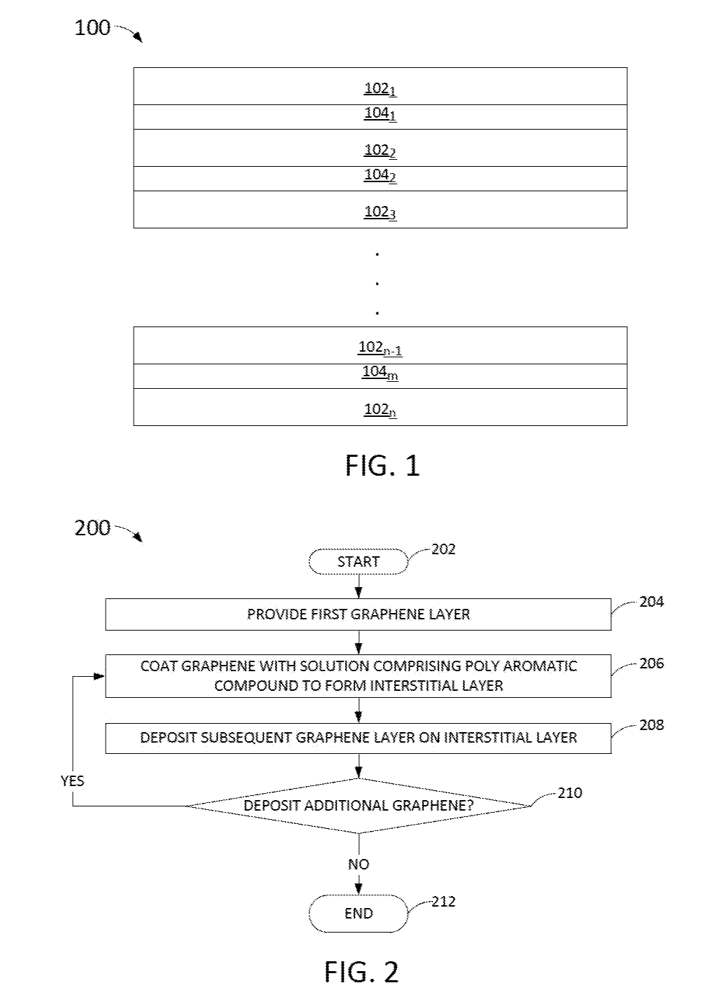

FIG. 1 illustrates a cross-sectional view of one embodiment of a multilayer graphene structure 100, according to the present disclosure. As illustrated, the structure 100 includes a plurality of graphene layers 102₁-102ₙ (hereinafter collectively referred to as “graphene layers 102”) and a plurality of interstitial layers 104₁-104ₘ (hereinafter collectively referred to as “interstitial layers 104”). Each pair of graphene layers 102 is separated by at least one interstitial layer 104.

In one embodiment, each graphene layer 102 comprises a monolayer of graphene (e.g., a one-atom-thick sheet of graphene). In a further embodiment, each graphene layer is produced over a large scale area (e.g., has dimensions up to approximately one hundred meters long and up to approximately 210 millimeters wide). The graphene layers 102 may be manufactured using any known technique for producing graphene, including roll-to-roll chemical vapor deposition (CVD) or transfer processes.

In one embodiment, each interstitial layer 104 comprises a monolayer of a polyaromatic compound. The polyaromatic compound comprises a compound that is capable of directed self-assembly on graphitic materials. To this end, the polyaromatic compound includes a polyaromatic core and one or more functional side groups. For instance, each interstitial layer 104 may comprise a polyaromatic compound such as a low-molecular weight compound (e.g., pyrene, triptycene, rylene, or any other polyarene), higher-molecular weight conjugated polymers, or other polyaromatic compounds that are capable of stacking via directed self-assembly on the surface of graphitic materials.

When a graphene layer 102 is coated with a polyaromatic compound, the anchoring functional groups of the polyaromatic compound interact strongly with the graphene in a manner that results in self-assembly of the interstitial layer 104. In particular, the π-π interactions between the aromatic rings of the polyaromatic compounds and the graphene form much stronger bonds than typical π-π interactions. In addition, polyaromatic compounds that bear a nitrogen-containing functional group (e.g., an amine) are capable of strong interactions with the surface of graphitic materials via charge transfer complexes. Thus, amine-functionalized pyrene derivatives or any other polyarene derivatives (e.g., phenanthrene, triptycene, rylene, or any other polyarene) and side-chain amine-functionalized conjugated polymers (e.g., polythiophenes) can form a monolayer on the surface of a graphene layer that will be very strongly bound by π-π stacking (e.g., attractive, noncovalent interactions between aromatic rings) and a charge transfer complex.

Since the polyaromatic compounds have a plane of symmetry, a graphene layer that has been coated with a polyaromatic compound can attract another layer of graphene by the same interactions. This ultimately results in an interstitial monolayer that is positioned between the graphene layers. The interstitial layer bonds the graphene layers together in a manner that mechanically strengthens the bonds between the graphene layers, enabling improved resistance to shearing and tensile stress. Alternating exposure to a solution of the polyaromatic compound and a dispersion of graphene layers, using a form of layer-by-layer stacking, for example, thus produces a robust assembly of intercalated graphene layers, where the different layers are held together by synergistic π-π stacking and charge transfer interactions.

The multilayer graphene structure 100 may comprise any number of graphene layers 102. Thus, by iterating the self-assembly of the interstitial layers 104 as needed, perfect control can be exercised over the number of graphene layers 102 and over the mechanical properties of the structure 100. The disclosed structure also allows for different degrees of reinforcement to be obtained between the graphene layers 102, based on the assembly of the interstitial layers 104. Moreover, different properties can be achieved in the structure 100 by varying the interstitial layers 104 at different locations in the structure 100 (e.g., different interstitial layers 104 may be formed from different low molecular eight and polymeric polyaromatic compounds and/or from different quantities of the same polyaromatic compounds).

As discussed above, a multilayer graphene structure assembled according to FIG. 1 allows the individual layers of graphene to uniformly share a load applied to the structure. The self-assembled interstitial layers form stable covalent bonds between the graphene layers that help the graphene to mitigate shear stress and to reinforce the domain boundary weak points.

FIG. 2 is a flow diagram illustrating a high level method 200 for fabricating a multilayer graphene structure, according to embodiments of the present disclosure. The method 200 may be carried out, for example, to form the multilayer graphene structure 100 illustrated in FIG. 1 and described in detail above. Accordingly, reference is made in the discussion of the method 200 to various elements of FIG. 1 to facilitate explanation.

The method 200 begins in step 202. In step 204, a first graphene layer 102ₙ is provided. In one embodiment, the first graphene layer 102ₙ comprises a monolayer of graphene (e.g., a one-atom-thick sheet of graphene). In a further embodiment, the first graphene layer 102ₙ is produced over a large scale area (e.g., has dimensions up to approximately one hundred meters long and up to approximately 210 millimeters wide). The first graphene layer 102ₙ may be manufactured using any known technique for producing graphene, including roll-to-roll chemical vapor deposition (CVD) or transfer processes.

In step 206, the first graphene layer 102ₙ is coated with a solution comprising a polyaromatic compound. The polyaromatic compound comprises a compound that is capable of directed self-assembly on graphitic materials. To this end, the polyaromatic compound includes a polyaromatic core and one or more functional side groups. For instance, the polyaromatic compound may comprise low-molecular weight pyrene, low-molecular phenanthrene, higher-molecular weight conjugated polymers, or other polyaromatic compounds that are capable of stacking via directed self-assembly on the surface of graphitic materials, such as amine-functionalized pyrene derivatives and side-chain amine-functionalized conjugated polymers (e.g., polythiophenes). The first graphene layer 102ₙ may be exposed to the solution by immersion, by spraying, in a roll to roll process from solution, or by other techniques. Step 206 results in a first interstitial layer 104ₘ being deposited on the first graphene layer 102ₙ.

In step 208, a second graphene layer 102ₙ₋₁ is deposited over the first interstitial layer 104ₘ. The second graphene layer 102ₙ₋₁ may be substantially similar in structure and composition to the first graphene layer 102ₙ. In one embodiment, the second graphene layer 102ₙ₋₁ is deposited via a solution that is applied to the first interstitial layer 104ₘ (e.g., by immersion, spraying, roll to roll process, or other techniques).

In step 210, it is determined whether additional layers of graphene are to be deposited. If the conclusion reached in step 210 is that no additional layers of graphene are to be deposited, then the method 200 ends in step 212. Alternatively, if the conclusion reached in step 210 is that at least one additional layer of graphene should be deposited, then the method 200 returns to step 206 and proceeds as described above to deposit a subsequent interstitial layer 104 and a subsequent graphene layer 102 according to the process described above.

It should be noted that the compositions of subsequent interstitial layers 104 do not necessarily need to be identical to the composition of the first interstitial layer 104ₘ. That is, the method 200 may be varied such that different interstitial layers 104 are formed from different types and/or quantities of polyaromatic compounds. This will allow the properties of the multilayer graphene structure 100 to be varied as needed for different applications.

The method 200 may be carried out from solution, which allows the various steps to be easily automated and scaled up for fabrication. The method 200 does not require a vacuum or high processing pressure, and can be carried out at substantially room temperature, although different temperatures and pressure ranges can be used to favor the interaction between the interstitial layers and the graphene layers.

The flowchart and block diagrams in the Figures illustrate the architecture, functionality, and operation of possible implementations of systems and methods according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A method, comprising:
providing a first layer of graphene;
providing a second layer of graphene; and
providing a first interstitial layer between the first layer of graphene and the second layer of graphene, wherein the first interstitial layer comprises a polyaromatic compound.

2. The method of claim 1, wherein the polyaromatic compound is a low molecular weight polyaromatic compound or a polymeric polyaromatic compound.

3. The method of claim 1, wherein the polyaromatic compound is a compound that is capable of directed self-assembly on a graphitic material.

4. The method of claim 1, wherein the polyaromatic compound comprises a polyarene.

5. The method of claim 4, wherein the polyarene comprises triptycene.

6. The method of claim 4, wherein the polyarene comprises a pyrene derivative.

7. The method of claim 4, wherein the polyarene comprises phenanthrene.

8. The method of claim 4, wherein the polyarene comprises rylene.

9. The method of claim 1, wherein the polyaromatic compound comprises a conjugated polymer.

10. The method of claim 1, wherein the polyaromatic compound bears a nitrogen-containing functional group.

11. The method of claim 10, wherein the nitrogen-bearing functional group is an amine

12. The method of claim 10, wherein the polyaromatic compound comprises an amine-functionalized pyrene derivative.

13. The method of claim 10, wherein the polyaromatic compound comprises a side-chain amine-functionalized conjugated polymer.

14. The method of claim 13, wherein the side-chain amine-functionalized conjugated polymer comprises a polythiophene.

15. The method of claim 1, further comprising:
providing a third layer of graphene; and
providing a second interstitial layer bonding the second layer of graphene to the third layer of graphene, wherein the second interstitial layer comprises a polyaromatic compound that is different from the polyaromatic compound comprising the first interstitial layer.

16. A method, comprising:
providing a plurality of layers of graphene; and
providing a plurality of interstitial layers formed of at least one polyaromatic compound,
wherein each pair of the plurality of layers of graphene is bonded by one of the plurality of interstitial layers, such that a structure comprising alternating layers of graphene and interstitial layers is formed.

17. The method of claim 16, wherein the polyaromatic compound is a low molecular weight polyaromatic compound or a polymeric polyaromatic compound.

18. The method of claim 16, wherein the polyaromatic compound comprises a polyarene.

19. The method of claim 1, wherein the polyaromatic compound comprises a conjugated polymer.

20. The method of claim 1, wherein the polyaromatic compound bears a nitrogen-containing functional group.
